(19) United States
(12) Patent Application Publication
(10) Pub. No.: US 2016/0086889 A1
(43) Pub. Date: Mar. 24, 2016

(54) CARBON NANOTUBE INTERCONNECT STRUCTURE, AND METHOD OF MANUFACTURING THE SAME

(71) Applicant: Kabushiki Kaisha Toshiba, Minato-ku (JP)

(72) Inventors: Masayuki Katagiri, Kawasaki (JP); Tadashi Sakai, Yokohama (JP)

(73) Assignee: Kabushiki Kaisha Toshiba, Minato-ku (JP)

(21) Appl. No.: 14/842,040

(22) Filed: Sep. 1, 2015

(30) Foreign Application Priority Data
Sep. 18, 2014 (JP) 2014-190567

(51) Int. Cl. H01L 23/532; H01L 21/311; H01L 21/768; H01L 23/528; H01L 23/522

(52) U.S. Cl. CPC H01L 23/53276; H01L 23/528; H01L 23/5226; H01L 21/76802; H01L 21/76877; H01L 21/7684; H01L 21/31116; H01L 2221/1094

(57) ABSTRACT

A carbon nanotube interconnect structure of an embodiment has a first interconnect layer, a first interlayer insulating film on the first interconnect layer, a second interlayer insulating film on the first interlayer insulating film, a contact hole penetrating through the first interlayer insulating film and the second interlayer insulating film, a catalyst metal film on a portion of the first interconnect layer located at a lower end of the contact hole, a second interconnect layer on the second interlayer insulating film, and carbon nanotubes on the catalyst metal film located in the contact hole. The carbon nanotubes electrically connecting the first interconnect layer and the second interconnect layer.

### CROSS-REFERENCE TO RELATED APPLICATION

This application is based upon and claims the benefit of priority from Japanese Patent Application No. 2014-190567, filed on Sep. 18, 2014; the entire contents of which are incorporated herein by reference.

### FIELD

Embodiments described herein relate to a carbon nanotube interconnect structure, and a method of manufacturing the same.

### BACKGROUND

As LSI circuits and 3D memories have become smaller and multilayered, increases of wiring delay in metal interconnects present serious problems. To reduce wiring delay, lowering interconnect resistance and reducing capacity between interconnects are critical. To achieve a lower interconnect resistance, low-resistance materials such as Cu have already been put into practical use. With Cu interconnects, however, there are problems such as reliability degradation due to stress migration or electromigration, higher electrical resistivity due to a size effect, and embedding in minute via holes. Therefore, there is a demand for an interconnect material that has low resistivity and excels in current density resistance.

Applications of carbon-based materials, such as carbon nanotubes and graphene, are now drawing attention as next-generation interconnect materials that can have a lower resistivity and higher reliability, exhibiting excellent physical properties such as high current density resistance, high electrical conduction properties, high heat conductivity, and high mechanical strength. Particularly, interconnect structures using carbon nanotubes as vertical interlayer interconnects with a high aspect ratio are being considered.

### BRIEF DESCRIPTION OF THE DRAWINGS

FIG. 1 is a cross-sectional view of an interconnect structure of a first embodiment;

FIG. 2 is a process chart of the formation of the first interlayer insulating film and the second interlayer insulating film in the interconnect structure of the first embodiment;

FIG. 3 is a process chart of the etching of the second interlayer insulating film in the interconnect structure of the first embodiment;

FIG. 4 is a process chart of the etching of the first interlayer insulating film in the interconnect structure of the first embodiment;

FIG. 5 is a process chart of the formation of the catalyst metal film in the interconnect structure of the first embodiment;

FIG. 6 is a process chart of the growth of the carbon nanotubes in the interconnect structure of the first embodiment;

FIG. 7 is a process chart of the formation of the embedded film in the interconnect structure of the first embodiment;

FIG. 8 is a process chart of the planarization in the interconnect structure of the first embodiment;

FIG. 9 is a cross-sectional view of an interconnect structure of a second embodiment;

FIG. 10 is a process chart of the formation of the catalyst metal film, the first interlayer insulating film, and the second interlayer insulating film in the interconnect structure of the second embodiment;

FIG. 11 is a process chart of the etching of the first interlayer insulating film in the interconnect structure of the second embodiment;

FIG. 12 is a process chart of the etching of the second interlayer insulating film in the interconnect structure of the second embodiment;

FIG. 13 is a process chart of the growth of the carbon nanotubes in the interconnect structure of the second embodiment;

FIG. 14 is a process chart of the formation of the embedded film in the interconnect structure of the second embodiment;

FIG. 15 is a process chart of the planarization in the interconnect structure of the second embodiment;

FIG. 16 is a cross-sectional view of an interconnect structure of a third embodiment; and

FIG. 17 is a cross-sectional view of an interconnect structure of a fourth embodiment.

### DETAILED DESCRIPTION

A carbon nanotube interconnect structure of an embodiment has a first interconnect layer, a first interlayer insulating film on the first interconnect layer, a second interlayer insulating film on the first interlayer insulating film, a contact hole penetrating through the first interlayer insulating film and the second interlayer insulating film, a catalyst metal film on a portion of the first interconnect layer located at a lower end of the contact hole, a second interconnect layer on the second interlayer insulating film, and carbon nanotubes on the catalyst metal film located in the contact hole. The carbon nanotubes electrically connecting the first interconnect layer and the second interconnect layer. A and B satisfy B/A>1.5, and L and a satisfy L/a≧2, where L represents a length of the contact hole, A represents an opening area at an upper end of the contact hole, a represents an opening diameter at the upper end of the contact hole, and B represents an opening area at the lower end of the contact hole.

A method of manufacturing a carbon nanotube interconnect structure of an embodiment has forming a first interconnect layer, forming a first interlayer insulating film on the first interconnect layer, forming a second interlayer insulating film on the first interlayer insulating film, forming a contact hole penetrating through the first interlayer insulating film and the second interlayer insulating film by performing etching on the first interlayer insulating film and the second interlayer insulating film, further performing etching on the first interlayer insulating film, to form a larger opening area than an upper end portion of the contact hole, forming a catalyst metal film in the contact hole, forming carbon nanotubes on the catalyst metal film, planarizing the carbon nanotubes; and forming a second interconnect layer on the planarized carbon nanotubes and the second interlayer insulating film.

A method of manufacturing a carbon nanotube interconnect structure of an embodiment has forming a first interconnect layer, forming a catalyst metal film on the first interconnect layer, forming a first interlayer insulating film on the catalyst metal film, forming a second interlayer insulating film on the first interlayer insulating film, forming a contact hole penetrating through the first interlayer insulating film and the second interlayer insulating film by performing etching on the first interlayer insulating film and the second interlayer insulating film, further performing etching on the first interlayer insulating film, to form a larger opening area than an upper end portion of the contact hole, forming carbon nanotubes on the catalyst metal film, planarizing the carbon nanotubes; and forming a second interconnect layer on the planarized carbon nanotubes and the second interlayer insulating film.

The electrical resistance of a carbon nanotube interconnect is determined by the number of carbon nanotubes formed in a contact hole. However, if the aspect ratio of the contact hole is 2 or higher, it is difficult to turn a catalyst metal film into nanopananoparticles at a high density through a plasma treatment or the like. As a result, carbon nanotubes are not obtained at a sufficiently high density, and the electrical resistance might not be lowered to a preferred level. In a case where the aspect ratio of the contact hole is high, and the interconnect width on the upper layer side needs to be reduced, the problem of a low carbon nanotube density tends to occur. Therefore, it is preferable to obtain carbon nanotubes at a high density, even if the catalyst metal film is not turned into nanoparticles at a high density in a contact hole having a high aspect ratio.

The following is a description of carbon nanotube interconnect structures through embodiments of interconnects, with reference to the accompanying drawings.

A carbon nanotube interconnect structure of a first embodiment includes: a first interconnect layer; a first interlayer insulating film on the first interconnect layer; a second interlayer insulating film on the first interlayer insulating film; a contact hole penetrating through the first interlayer insulating film and the second interlayer insulating film; a catalyst metal film on the portion of the first interconnect layer located at the lower end of the contact hole; a second interconnect layer on the second interlayer insulating film; carbon nanotubes on the portion of the catalyst metal film located in the contact hole, the carbon nanotubes electrically connecting the first interconnect layer and the second interconnect layer; and an embedded film or a void between the carbon nanotubes.

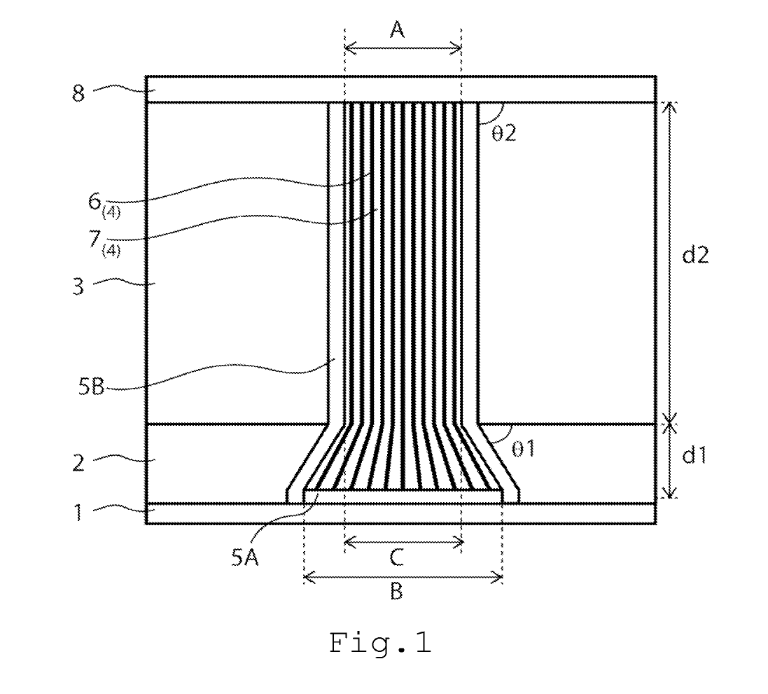

FIG. 1 is a cross-sectional view of the carbon nanotube interconnect structure of the first embodiment. The carbon nanotube interconnect structure shown in FIG. 1 is a structure for an interlayer interconnect in a semiconductor device, for example. The semiconductor device is not particularly limited, and may be a microcomputer, an MPU (Micro-Processing Unit), a PLD (Programmable Logic Device), or a three-dimensional NAND flash memory, for example. Specific examples of usage of the carbon nanotube interconnect of the first embodiment include a contact plug that connects blocks of a BiCS memory structure having a high aspect ratio (interconnect length/opening diameter).

The carbon nanotube interconnect structure shown in FIG. 1 includes a first interconnect layer 1, a first interlayer insulating film 2, a second interlayer insulating film 3, a catalyst metal film 5 (catalyst metal films 5A and 5B), carbon nanotubes 6 (in a contact hole 4), a embedded film 7 (in the contact hole 4), and a second interconnect layer 8.

The first interconnect layer 1 is a so-called lower interconnect layer made of a conductive material such as Cu. The first interconnect layer 1 is an internal interconnect layer of a semiconductor device or the like. In the interconnect layer, a semiconductor circuit may be provided. The first interconnect layer 1 is electrically connected to the carbon nanotubes 6 via the catalyst metal film 5.

The first interlayer insulating film 2 is an insulating film interposed between the first interconnect layer 1 and the second interlayer insulating film 3. The first interlayer insulating film 2 is designed to surround the contact hole 4 in which the carbon nanotubes 6 and the embedded film 7 are provided, and the catalyst metal film 5B. The thickness of the first interlayer insulating film 2 (the thickness in the penetrating direction of the contact hole 4) is represented by d1. The opening area of the first interlayer insulating film (the opening area of the opening of the first interlayer insulating film 2 on the side of the first interconnect layer 1) is preferably larger than the opening area of the second interlayer insulating film 3 (the opening area of the opening of the second interlayer insulating film 3 on the side of the second interconnect layer 8). So as to make the opening areas differ from each other, the first interlayer insulating film 2 and the second interlayer insulating film 3 are preferably insulating films made of materials having different etching rates from each other. For example, the permittivity of the first interlayer insulating film 2 is preferably higher than the permittivity of the second interlayer insulating film 3. Therefore, the first interlayer insulating film 2 is preferably a silicon nitride film, and is a high-permittivity insulating film such as a SiN film or a SiCN film having a higher permittivity than 4. The first interlayer insulating film 2 may be a single-layer film, or may be formed with layers of different materials. The permittivity of the second interlayer insulating film 3 may be higher than the permittivity of the first interlayer insulating film 2, which is the opposite of the above described arrangement.

The second interlayer insulating film 3 is an insulating film interposed between the first interlayer insulating film 2 and the second interconnect layer 8. The second interlayer insulating film 3 is designed to surround the contact hole 4 in which the carbon nanotubes 6 and the embedded film 7 are provided, and the catalyst metal film 5B. The thickness of the second interlayer insulating film 3 (the thickness in the penetrating direction of the contact hole 4) is represented by d2. For the same reasons as the reasons explained in the description of the first interlayer insulating film 2, the second interlayer insulating film 3 is preferably a silicon oxide film having a lower permittivity than the insulating film material used in the first interlayer insulating film 2, and is a low-permittivity insulating film such as a SiO₂ film or a SiOC film. The second interlayer insulating film 3 may be a single-layer film, or may be formed with layers of different materials.

The contact hole 4 is a region interposed between the first interconnect layer 1 and the second interconnect layer 8. The catalyst metal film 5A is provided at the bottom portion of the contact hole 4. In the contact hole 4, a large number of carbon nanotubes 6 are provided, and the embedded film 7 is provided between the carbon nanotubes 6. At the upper end opening portion of the contact hole 4, the carbon nanotubes 6 are electrically and physically connected to the second interconnect layer 8. At the lower end opening portion of the contact hole 4, the carbon nanotubes 6 are electrically and physically connected to the first interconnect layer 1 via the catalyst metal film 5A, which has been nanoparticulated.

The opening area A at the upper end of the contact hole 4 (the interface between the contact hole 4 and the second interconnect layer 8) is preferably smaller than the opening area B at the lower end of the contact hole 4. That is, at least the relationship, B/A>1, is preferably satisfied. The contact hole 4 preferably has a tapered shape, with the upper end being the narrower end. The opening areas A and B of the contact hole 4 do not include the thickness of the catalyst metal film 5.

The interconnect structure of this embodiment has an interconnect formed with carbon nanotubes grown from the nanoparticulated catalyst metal film 5A at the bottom portion of the contact hole 4. In an interconnect structure in which the contact hole 4 has a high aspect ratio, nanoparticulating the catalyst metal film 5 is more difficult than in an interconnect structure in which the aspect ratio of the contact hole 4 is low (lower than 2). If the catalyst metal film 5 is not easily nanoparticulated, the density of carbon nanotubes 6 (the number of carbon nanotubes 6 per square centimeter) becomes lower. Therefore, if the opening areas at the upper end and the lower end of the contact hole 4 are the same in a case where the aspect ratio of the contact hole 4 is high, the density of carbon nanotubes 6 in the contact hole 4 is low. However, even in a case where the nanoparticulated proportion in the catalyst metal film 5 is small, the absolute number of nanoparticles in the catalyst metal film 5A at the bottom portion of the contact hole 4 can be increased by making the area of the bottom portion (the lower end) of the contact hole 4 larger than the opening area at the upper end of the contact hole 4. In view of this, to increase the density of carbon nanotubes 6 in the contact hole 4 surrounded by the second interlayer insulating film 3, the relationship, B/A>1.5, is preferably satisfied. More preferably, the relationship, B/A>2, is satisfied. The opening areas can be determined from images taken with a scanning electron microscope or a transmission electron microscope. The image magnification ratio is appropriately set in accordance with the opening areas of the contact hole 4.

The opening area C of the contact hole 4 at the boundary between the first interlayer insulating film 2 and the second interlayer insulating film 3 preferably satisfies the relationship, A≦C<B. If the opening area C is smaller than the opening area A, the carbon nanotubes 6 are stuck in the contact hole 4 at the boundary between the first interlayer insulating film 2 and the second interlayer insulating film 3 during the stage of growth of the carbon nanotubes 6. As a result, the growth of the carbon nanotubes 6 becomes insufficient, and the number of carbon nanotubes 6 that do not reach the second interconnect layer 8 becomes larger, which is not preferable.

The length L of the contact hole 4 is the length from the first interconnect layer 1 to the second interconnect layer 8. The length L of the contact hole 4 is not smaller than 100 nm and not greater than 3 μm, for example. The aspect ratio of the contact hole 4 of this embodiment is determined based on the opening diameter at the upper end of the contact hole 4. In a case where the contact hole 4 has circular openings, the diameter determined from a cross-sectional image of the interconnect structure is set as the opening diameter a at the upper end of the contact hole 4. In a case where the openings of the contact hole 4 do not have circular shapes, the opening area A of the contact hole 4 is determined, and the opening diameter a is determined from the equation, a=(A/π)^{1/2} Likewise, an opening diameter b and an opening diameter c are determined from the values determined from cross-sectional images of the interconnect structure, or from the opening area B((B/π)^{1/2}) and the opening area C((C/π)^{1/2}). The opening areas, the opening diameters, and the length L of the contact hole 4 can be determined from images taken with a scanning electron microscope or a transmission electron microscope. The image magnification ratio is appropriately set in accordance with the opening areas of the contact hole 4, the interconnect length, or the like.

The opening diameter a in this embodiment is determined by the interconnect width of the second interconnect layer 8, and is not smaller than 50 nm and not greater than 100 nm, for example. The opening diameter b is determined by the interconnect width of the first interconnect layer 1, and is not smaller than 60 nm and not greater than 300 nm, for example. In a case where the carbon nanotube interconnect is used in a BiCS memory that is a 3D memory, for example, the upper end portion of the contact hole 4 is connected to the second interconnect layer 8 having a small area. Therefore, the upper end portion of the contact hole 4 is required to have a very small diameter such as 100 nm or smaller. On the other hand, the bottom portion of the contact hole 4 is connected to the first interconnect layer 1 having a large area, and can have a diameter of 100 nm or greater, such as 150 nm.

The thickness d1 of the first interlayer insulating film 2 is not smaller than 5 nm and not greater than 100 nm, for example. The thickness d2 of the second interlayer insulating film 3 is not smaller than 95 nm and not greater than 2900 nm, for example. As for the ratio between d1 and d2, if d1 is too large, the etching time for the first interlayer insulating film 2 becomes longer, which is not preferable. Therefore, the relationship, d1/d2>0.04, is preferably satisfied.

The angle θ1 of the contact hole 4 in the region surrounded by the first interlayer insulating film 2 is smaller than 90 degrees. If the angle θ1 is too small, the sloped portion of the contact hole 4 becomes steeper, and the growth of the carbon nanotubes 6 might become insufficient. If the angle θ1 is large, the effect to increase the density of the carbon nanotubes 6 becomes smaller. Therefore, the angle θ1 preferably satisfies the relationship, 45°≦θ1≦85°. The angle θ2 of the contact hole 4 in the region surrounded by the second interlayer insulating film 3 satisfies the relationship, θ1<θ2≦90°. As θ1 and θ2 satisfy the above relationships, the density of the carbon nanotubes 6 becomes higher by virtue of different opening areas, and contribute to a decrease in interconnect resistance. So as to increase the density of the carbon nanotubes 6, too large a difference between θ1 and θ2 is not preferable, and the relationship, θ2/θ1<2, is preferably satisfied. θ1 and θ2 are determined from the following equations:

cot θ1=(b−c)/2d1 (Equation 1)

cot θ2=(c−a)/2d1 (Equation 2)

As the aspect ratio of the contact hole 4 becomes higher, the nanoparticulation rate in the catalyst metal film 5 becomes lower, and therefore, the effect to increase the density of the carbon nanotubes 6 of this embodiment becomes greater. In view of this, the aspect ratio of the contact hole 4 in the carbon nanotube interconnect structure of this embodiment is preferably 10 or higher, and more preferably, 30 or higher. In the carbon nanotube interconnect structure of this embodiment, even if the aspect ratio is a very high value such as 30, the carbon nanotubes 6 at a high density such as 10¹²/cm² or higher can connect the interconnect layers to each other in the region surrounded by the second interlayer insulating film 3.

The catalyst metal film 5 is a metal film provided on the sidewall and at the bottom portion of the contact hole 4. The catalyst metal film 5 may be made of a metal selected from the group consisting of Co, Ni, Fe, Cu, Ru, Pt, and the like, which are materials having a catalytic action suitable for the growth of the carbon nanotubes 6, an alloy containing the metal, or an alloy containing two or more metals selected from the above group, for example. The thickness of the catalyst metal film 5 is not smaller than 1 nm and not greater than 5 nm, which is suitable for the growth of the carbon nanotubes 6. A foundation metal film (not shown) may be provided between the catalyst metal film 5A and the first interconnect layer 1 at the bottom portion of the contact hole 4. The foundation metal film is a thin film containing Ti, TiN, or TaN, a thin film made of Ti, TiN, or TaN, or a film stack formed with a Ti film, a TiN film, and a TaN film. The thickness of the foundation metal film is not smaller than 1 nm and not greater than 20 nm, for example. A catalyst metal inactivating film (not shown) is preferably provided between the catalyst metal film 5B and the first interlayer insulating film 2, and between the catalyst metal film 5B and the second interlayer insulating film 3. With the catalyst metal inactivating film, the carbon nanotubes 6 are prevented from growing from the sidewall of the contact hole 4. The catalyst metal inactivating film is a thin film containing Si, SiO₂, or SiN, a thin film made of Si, SiO₂, or SiN, or a thin film stack formed with a combination of any two or more of a Si thin film, a SiO₂ thin film, and a SiN thin film, for example. The thickness of the catalyst metal inactivating film is not smaller than 1 nm and not greater than 10 nm, for example. Alternatively, the catalyst metal film 5B may be designed to have a thickness of 10 nm or greater, for example, so that graphene grows from the sidewall of the contact hole 4. A diffusion preventive film and a conductive film may be formed between the catalyst metal film 5 and the first interlayer insulating film 2, and between the catalyst metal film 5 and the second interlayer insulating film 3. The diffusion preventive film is preferably used to prevent the conductive film and the catalyst metal film 5 from diffusing into the first interlayer insulating film 2 and the second interlayer insulating film 3. The conductive film is preferably provided under the catalyst metal film 5 so as to stabilize and improve the conductivity of the interlayer interconnects, and is preferably made of a metal serving as a promoter of carbon nanotube growth. A metal film can be used as the conductive film, and the metal film preferably contains one or more elements selected from the group consisting of Ti, Ta, Mn, Mo, and V.

The carbon nanotubes 6 electrically connect the first interconnect layer 1 and the second interconnect layer 8. The carbon nanotubes 6 grow from the nanoparticulated catalyst metal film 5A at the bottom portion of the contact hole 4. Each of the carbon nanotubes 6 may be a single wall, or may be formed with more than one wall. Dopant may be included in the carbon nanotubes 6. With the dopant, the diameter of each of the carbon nanotubes 6 can be made larger, and the void-filling rate can be increased. Examples of the dopant for the carbon nanotubes 6 include atoms and molecules of alkali metals (such as K, Rb, and Li), halogens (such as F₂ and Br₂), and chlorides (such as FeCl₃, ZnCl₂, CdCl₂, YCl₃, and AlCl₃). Each of the carbon nanotubes 6 may have a bent shape, a curved shape, or a linear shape, or may have two or more of those shapes. The density of the carbon nanotubes 6 in the region surrounded by the second interlayer insulating film 3 is preferably 10¹²/cm² or higher, so as to lower the interconnect resistance.

The embedded film 7 is a conductive or insulative embedded film. A conductive embedded film may be a Cu film formed by plating, for example. An insulative embedded film may be a SOD (Spin On Dielectric) film, for example. The embedded film 7 is the material used for giving mechanical strength to the carbon nanotubes 6. The embedded film 7 may not be provided in a case where the carbon nanotubes 6 have high strength by virtue of a high void-filling rate, for example.

The second interconnect layer 8 is a so-called upper interconnect layer made of a conductive material such as Ti. The second interconnect layer 8 is preferably made of Ti that forms excellent contact with the carbon nanotubes 6. The second interconnect layer 8 is an internal interconnect layer of a semiconductor device or the like. In the interconnect layer, a semiconductor circuit may be provided. The second interconnect layer 8 is electrically connected to the carbon nanotubes 6. A conductive material such as Cu may be further provided on the second interconnect layer 8.

According to this embodiment, the area of the bottom portion of the contact hole 4 at which the catalyst metal film for carbon nanotube growth is provided can be made larger than the area of the upper end opening portion of the contact hole 4, and the density of the carbon nanotubes 6 at the upper end opening portion of the contact hole 4 can be made higher than the density of the carbon nanotubes 6 at the bottom portion of the contact hole 4. In a case where the aspect ratio of the contact hole 4 is high, and the interconnect width of the second interconnect layer 8 is small, the interconnect width of the first interconnect layer 1 on the lower interconnect side is increased, and the region in which the carbon nanotubes 6 can grow is widened, so that the density of the carbon nanotubes 6 on the side of the second interconnect layer 8 that is the upper interconnect side can be increased, and a carbon nanotube interconnect that has low resistance though being a narrow interconnect can be provided as in this embodiment. Also, as the density of the carbon nanotubes 6 increases, uneven polishing during the planarizing process can be avoided, and the structural stability of the contact hole 4 can increase. Furthermore, as the density of the carbon nanotubes 6 at the bottom portion of the contact hole 4 is relatively low, pullout during the initial growth when the carbon nanotubes 6 are bundled can be prevented.

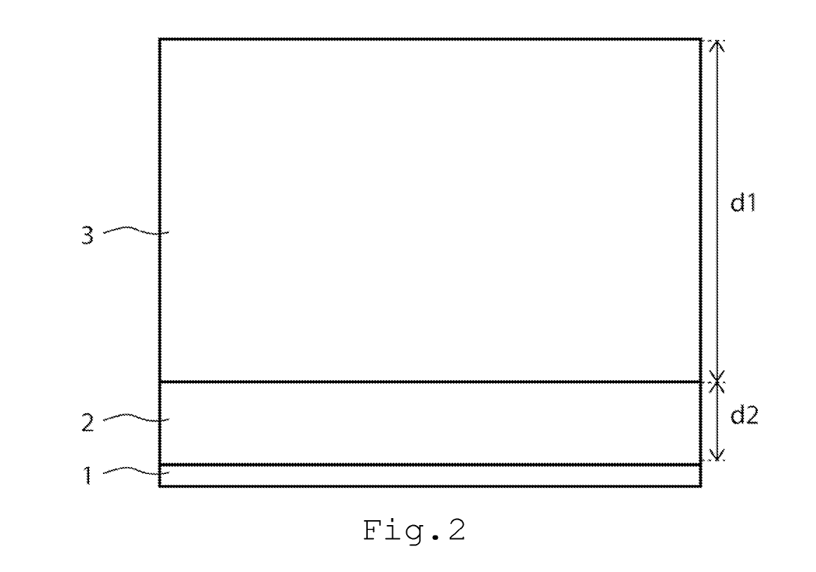

Referring now to the process charts in FIGS. 2 through 8, a method of manufacturing the carbon nanotube interconnect structure of the first embodiment is described. The method of manufacturing the carbon nanotube interconnect structure of this embodiment includes: the step of forming a first interconnect layer; the step of forming a first interlayer insulating film on the first interconnect layer; the step of forming a second interlayer insulating film on the first interlayer insulating film; the step of forming a contact hole penetrating through the first interlayer insulating film and the second interlayer insulating film by performing etching on the first interlayer insulating film and the second interlayer insulating film; the step of further performing etching on the first interlayer insulating film so as to form a larger opening area than the upper end portion of the contact hole; the step of forming a catalyst metal film in the contact hole; the step of forming carbon nanotubes on the catalyst metal film; the step of planarizing the carbon nanotubes; and the step of forming a second interconnect layer on the planarized carbon nanotubes and the second interlayer insulating film.

FIG. 2 is a process chart of the formation of the first interlayer insulating film 2 and the second interlayer insulating film 3 in the interconnect structure of the first embodiment. First, the first interlayer insulating film 2 and the second interlayer insulating film 3 are formed on the first interconnect layer 1. The first interlayer insulating film 2 and the second interlayer insulating film 3 are formed by CVD (Chemical Vapor Deposition), for example.

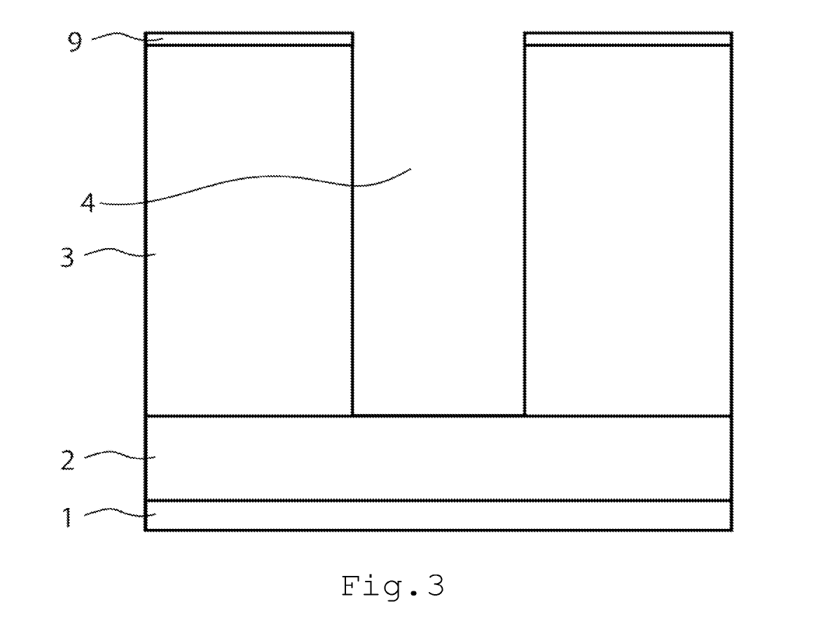

FIG. 3 is a process chart of the etching of the second interlayer insulating film 3 in the interconnect structure of the first embodiment. As shown in FIG. 3, a mask 9 is formed, and dry etching is performed with a fluorine-containing gas such as CF₄ or CF₄ having oxygen added thereto, so that the second interlayer insulating film 3 is penetrated to expose the first interlayer insulating film 2.

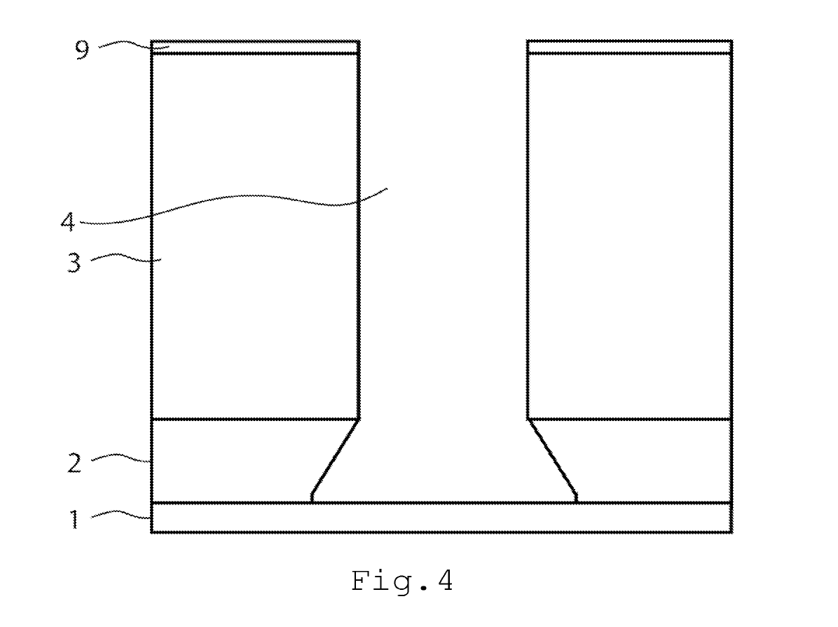

FIG. 4 is a process chart of the etching of the first interlayer insulating film 2 in the interconnect structure of the first embodiment. Dry etching is performed with a different fluorine-containing gas from that used in the etching of the second interlayer insulating film 3, such as CH₂F₂ or CH₃F₂, or CH₂F₂ or CH₃F₂ having oxygen added thereto, so that the first interlayer insulating film 2 is penetrated to expose the first interconnect layer 1, and the contact hole 4 is formed. At this point, the opening at the bottom portion of the contact hole 4 is made larger than the opening at the upper end of the second interlayer insulating film 3. The etching time for the first interlayer insulating film 2 is preferably long, so that the portion of the contact hole 4 penetrating through the first interlayer insulating film 2 has an inverse tapered shape. After the contact hole 4 is formed, the mask 9 is removed.

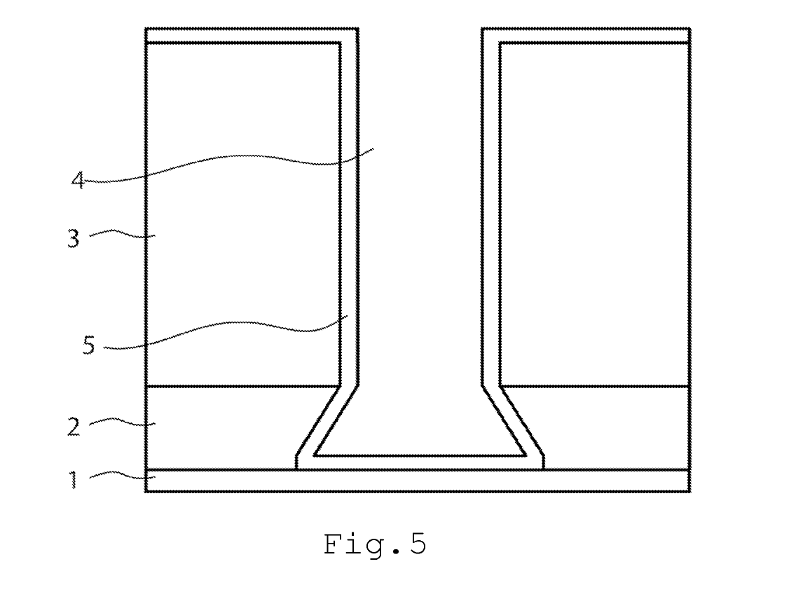

FIG. 5 is a process chart of the formation of the catalyst metal film 5 in the interconnect structure of the first embodiment. As shown in FIG. 5, the catalyst metal film 5 is formed on the entire surface including the contact hole 4. The method of forming the catalyst metal film 5 may be a film forming method such as PVD (Physical Vapor Deposition) or CVD. In a case where the aspect ratio of the contact hole 4 is high, however, it is difficult to form a catalyst metal film at the bottom of the via by PVD such as a sputtering technique with a low uneven-surface coatability. Therefore, it is preferable to form the film by CVD with a high uneven-surface coatability.

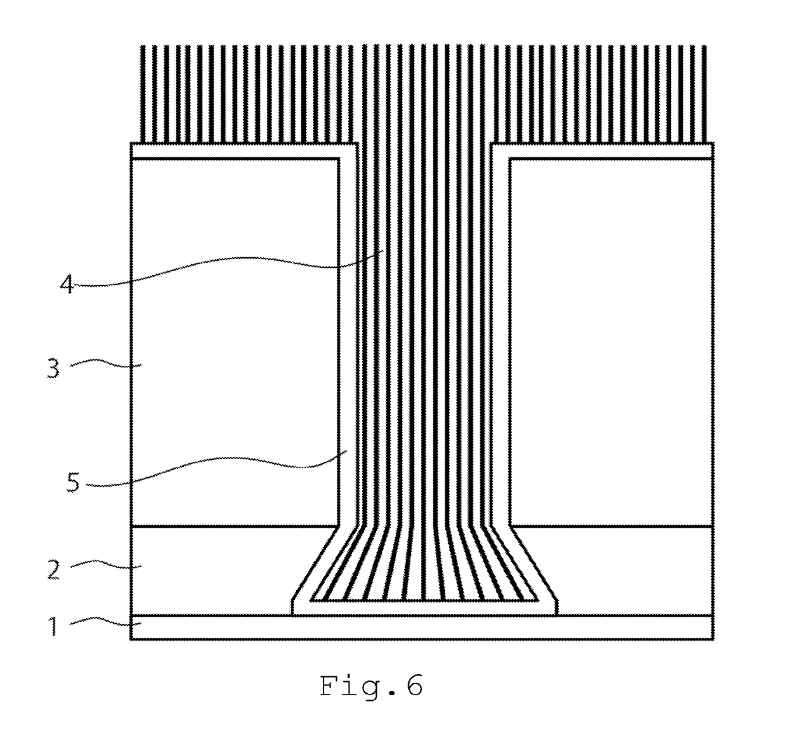

FIG. 6 is a process chart of the growth of the carbon nanotubes 6 in the interconnect structure of the first embodiment. As shown in FIG. 6, the carbon nanotubes 6 are grown from the catalyst metal film 5. The carbon nanotubes 6 are grown by thermal CVD or plasma CVD, for example. By plasma CVD, a substrate in a reacting furnace is heated to 500° C., for example, a hydrocarbon-containing gas such as a methane gas is introduced as a source gas, hydrogen is introduced as a carrier gas, and the methane gas is excited and discharged by microwaves, for example, so that the source gas turns into plasma and reacts with the catalyst metal film 5, and the carbon nanotubes 6 are grown. When the carbon nanotubes 6 are grown, the catalyst metal film 5 may be nanoparticulated through a plasma surface treatment. The source gas of the plasma is preferably a rare gas such as hydrogen or argon, or may be a mixed gas containing hydrogen and/or argon. At this point, the substrate may be heated. Even if the plasma treatment for nanoparticulating the catalyst metal film 5 is skipped, the catalyst metal film 5 is nanoparticulated by the heat applied to grow the carbon nanotubes 6.

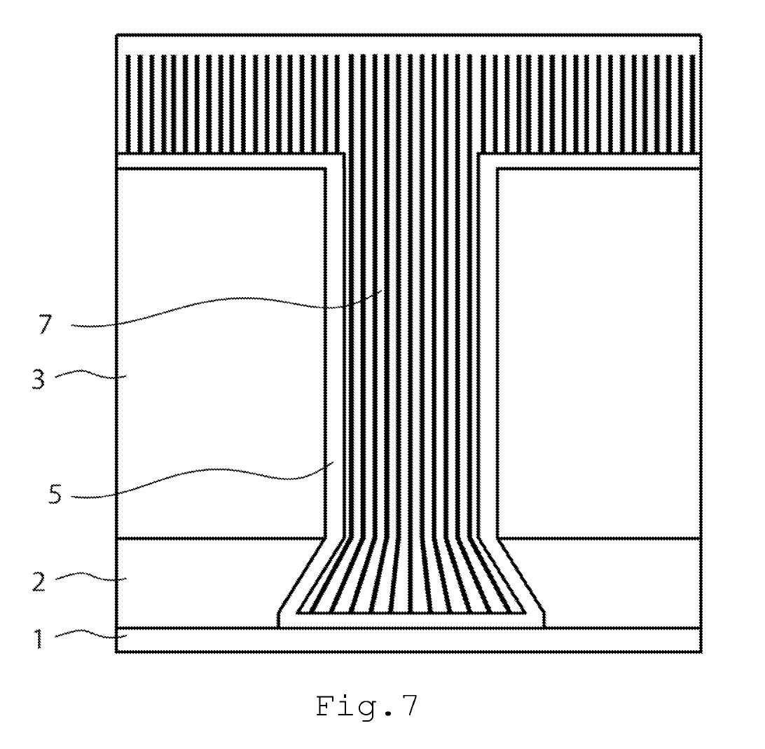

FIG. 7 is a process chart of the formation of the embedded film 7 in the interconnect structure of the first embodiment. The embedded film 7 is formed to secure the carbon nanotubes 6 so that polishing is appropriately performed at the time of planarization by CMP (Chemical Mechanical Polishing). The embedded film 7 may be made of an insulative material or a conductive material, and a SOD that is a coated insulating film is formed by spin coating. After the spin coating, the resultant film is hardened at 400° C., for example. As described above, this step can be skipped by adding the step of doping the carbon nanotubes 6 or the like.

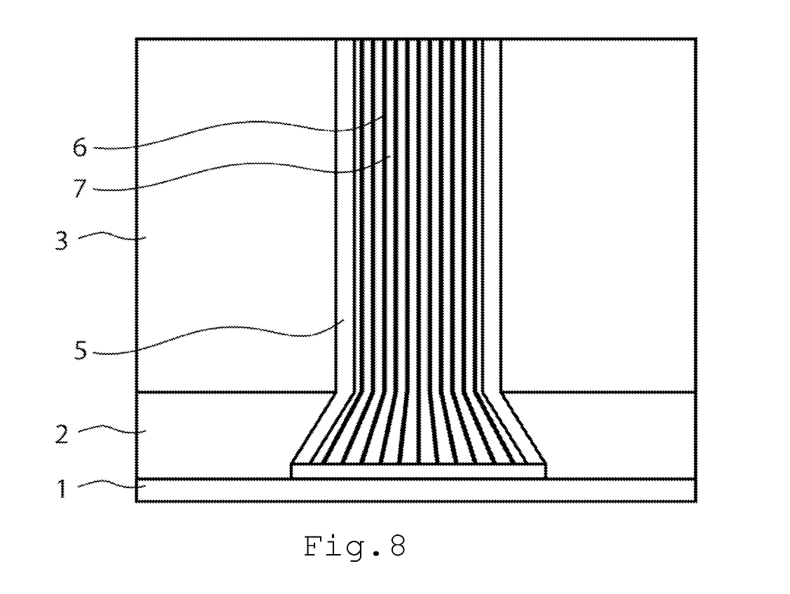

FIG. 8 is a process chart of the planarization in the interconnect structure of the first embodiment. Planarization is performed by CMP, and an interconnect structure having the carbon nanotubes 6 and the embedded film 7 formed in the contact hole 4 is obtained. The second interconnect layer 8 is then formed on the carbon nanotubes 6, and the carbon nanotube interconnect structure shown in FIG. 1 is obtained.

### Second Embodiment

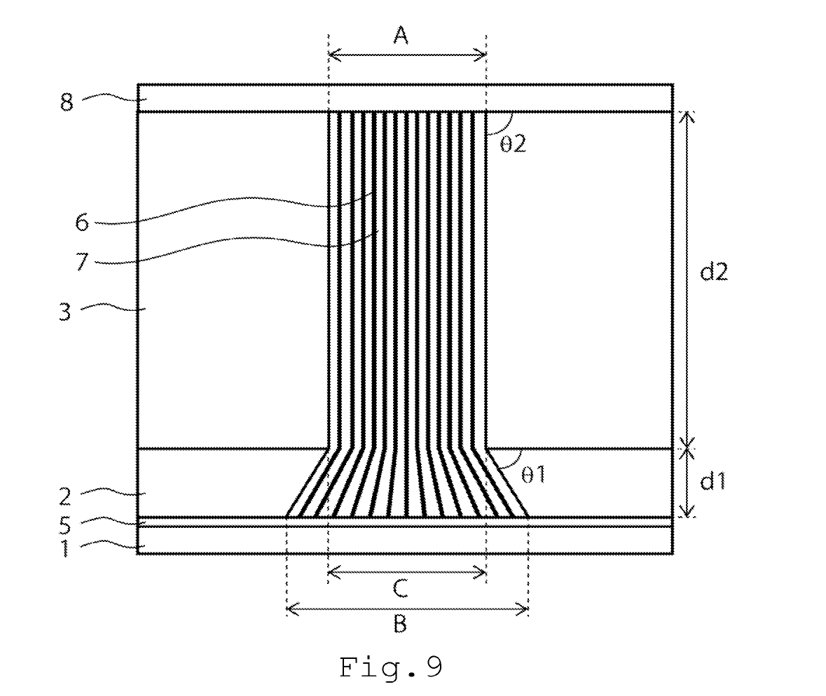

FIG. 9 shows a cross-section structure of a second embodiment. The difference from the first embodiment is that the catalyst metal film 5 is not provided on the sidewall of the contact hole 4, but is provided at the bottom portion of the contact hole 4 and between the first interconnect layer 1 and the first interlayer insulating film 2. Therefore, a carbon nanotube interconnect structure of the second embodiment includes: a first interconnect layer 1; a first interlayer insulating film 2 on the first interconnect layer 1; a second interlayer insulating film 3 on the first interlayer insulating film 2; a contact hole 4 penetrating through the first interlayer insulating film 2 and the second interlayer insulating film 3; a catalyst metal film 5 on the portion of the first interconnect layer 1 located at the lower end of the contact hole 4; a second interconnect layer 8 on the second interlayer insulating film 3; and carbon nanotubes 6 on the portion of the catalyst metal film 5 located in the contact hole 4, the carbon nanotubes 6 electrically connecting the first interconnect layer 1 and the second interconnect layer 8, wherein A and B satisfy the relationship, B/A>1.5, and L and a satisfy the relationship, L/a (aspect ratio)≧2, where L represents the length of the contact hole 4, A represents the opening area at the upper end of the contact hole 4, a represents the opening diameter at the upper end of the contact hole 4, and B represents the opening area at the lower end of the contact hole 4. The catalyst metal film 5 is further provided between the first interconnect layer 1 and the first interlayer insulating film 2. The carbon nanotube interconnect structure of the second embodiment is the same as that of the first embodiment, except for the location of the catalyst metal film 5. Therefore, the components of the second embodiment and the structures of those components are not explained herein.

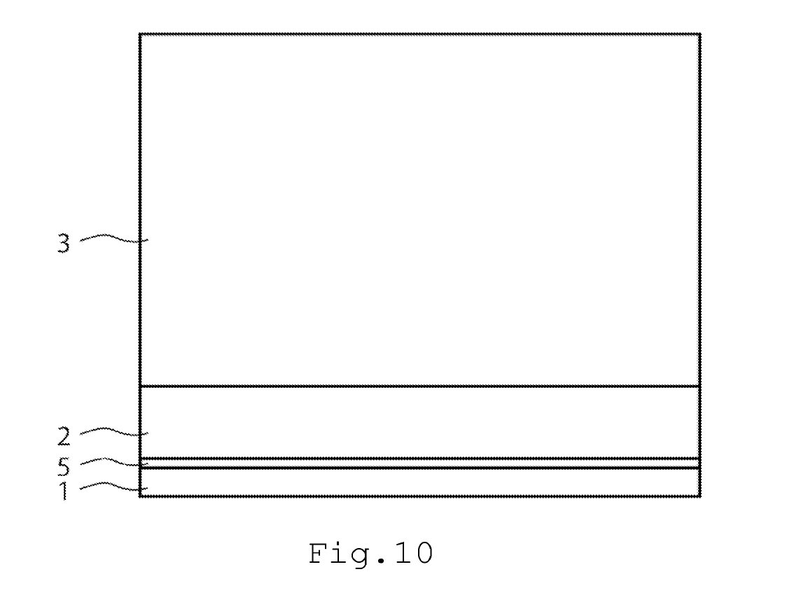

Referring now to the process charts in FIGS. 10 through 15, a method of manufacturing the carbon nanotube interconnect structure of the second embodiment is described. The method of manufacturing the carbon nanotube interconnect structure of this embodiment includes: the step of forming a first interconnect layer; the step of forming a catalyst metal film on the first interconnect layer; the step of forming a first interlayer insulating film on the catalyst metal film; the step of forming a second interlayer insulating film on the first interlayer insulating film; the step of forming a contact hole penetrating through the first interlayer insulating film and the second interlayer insulating film by performing etching on the first interlayer insulating film and the second interlayer insulating film; the step of further performing etching on the first interlayer insulating film so as to form a larger opening area than the upper end portion of the contact hole; the step of forming carbon nanotubes on the catalyst metal film; the step of planarizing the carbon nanotubes; and the step of forming a second interconnect layer on the planarized carbon nanotubes and the second interlayer insulating film.

FIG. 10 is a process chart of the formation of the catalyst metal film, the first interlayer insulating film, and the second interlayer insulating film in the interconnect structure of the second embodiment. As shown in FIG. 10, the catalyst metal film 5 is first formed on the first interconnect layer 1. Since any uneven-surface coatability is not required in the second embodiment, the catalyst metal film 5 may be formed by CVD, or the catalyst metal film 5 may be formed by PVD, regardless of the aspect ratio of the contact hole 4. The first interlayer insulating film 2 and the second interlayer insulating film 3 are then formed on the catalyst metal film 5 in the same manner as in the first embodiment.

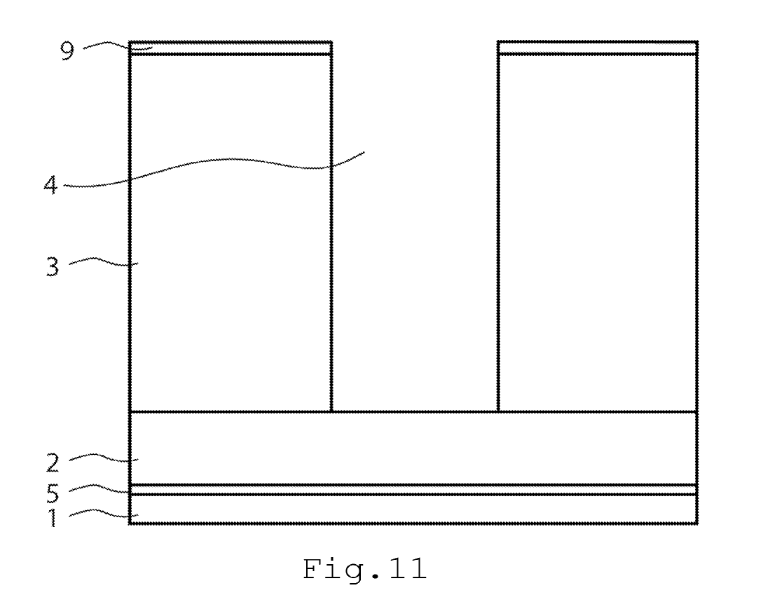

FIG. 11 is a process chart of the etching of the first interlayer insulating film 2 in the interconnect structure of the second embodiment. Etching is performed on the first interlayer insulating film 2 in the same manner as in the first embodiment.

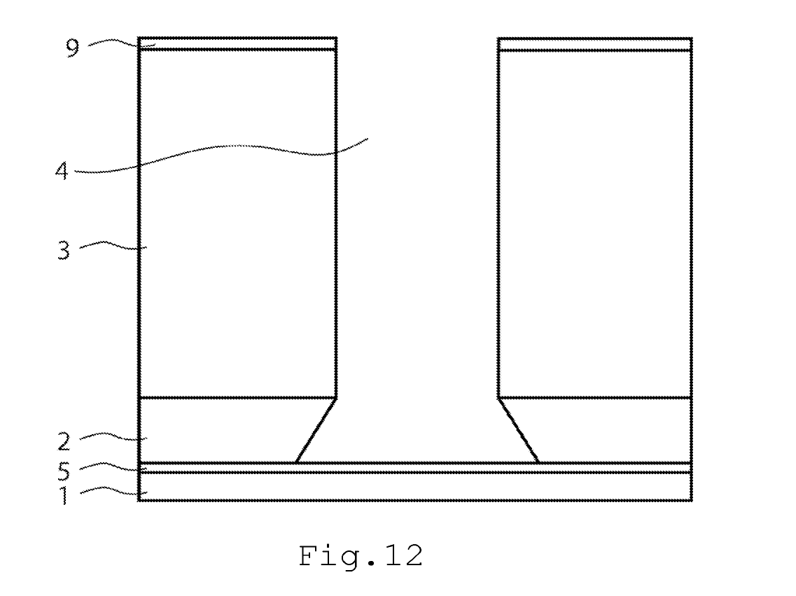

FIG. 12 is a process chart of the etching of the second interlayer insulating film 3 in the interconnect structure of the second embodiment. Dry etching is performed on the second interlayer insulating film 3 in the same manner as in the first embodiment.

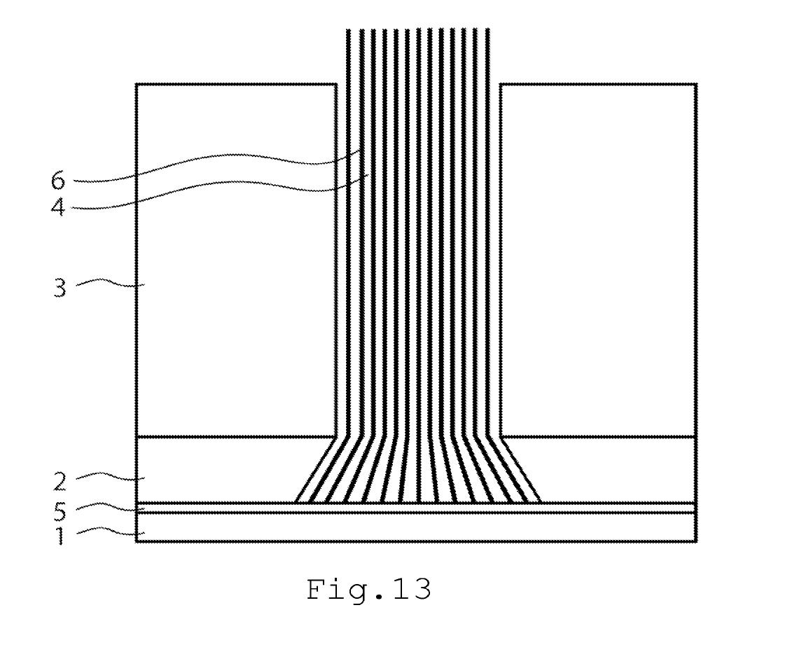

FIG. 13 is a process chart of the growth of the carbon nanotubes 6 in the interconnect structure of the second embodiment. As shown in FIG. 13, the carbon nanotubes 6 are grown from the catalyst metal film 5. Although the catalyst metal film 5 does not exist on the sidewall of the contact hole 4, the carbon nanotubes 6 can be grown in the same manner as in the first embodiment.

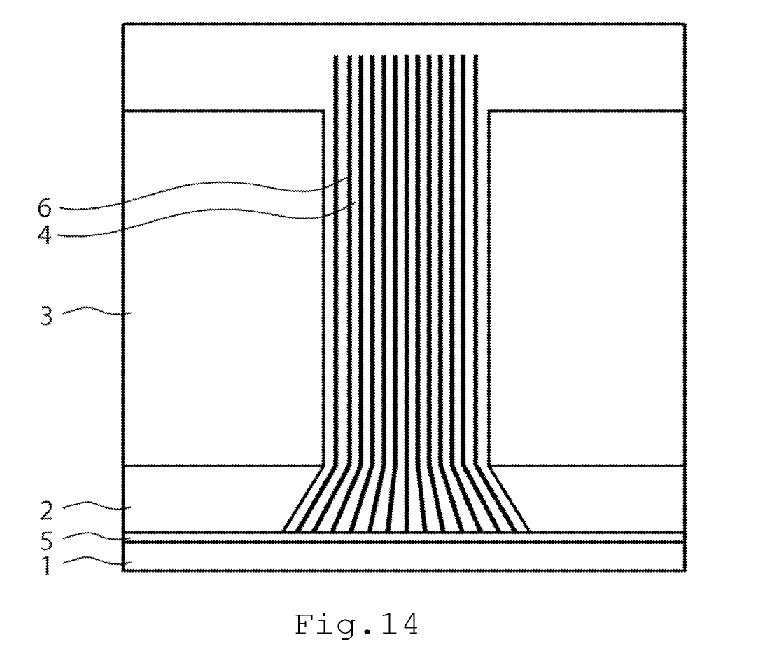

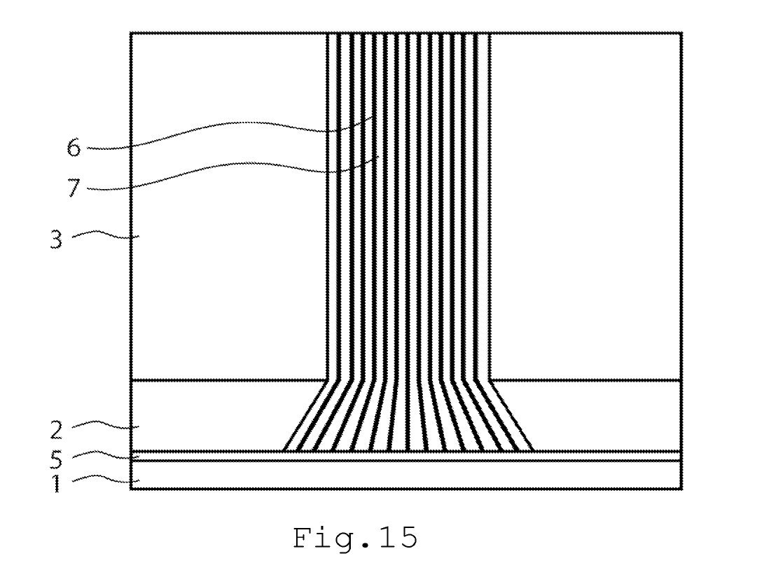

FIG. 14 is a process chart of the formation of the embedded film 7 in the interconnect structure of the second embodiment. FIG. 15 is a process chart of the planarization in the interconnect structure of the second embodiment. The processes shown in FIGS. 14 and 15 are the same as the corresponding processes in the first embodiment. The second interconnect layer 8 is then formed on the carbon nanotubes 6, and the carbon nanotube interconnect structure shown in FIG. 9 is obtained.

### Third Embodiment

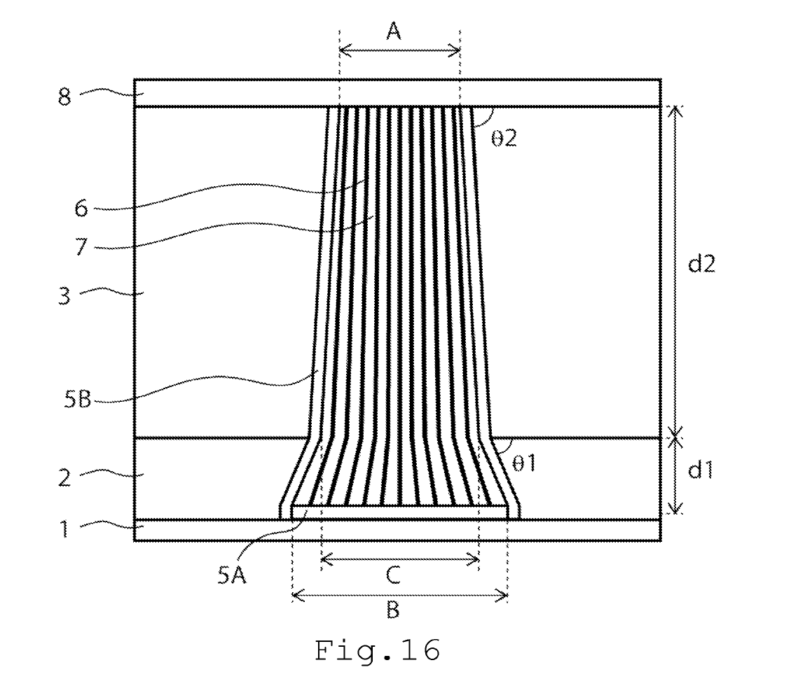

A third embodiment is a modification of the embodiment shown in FIG. 1. FIG. 16 is a cross-sectional view of a carbon nanotube interconnect structure of the third embodiment. The third embodiment differs from the embodiment shown in FIG. 1 in that the angle θ1 is smaller than 90 degrees. Except for the angle θ1, the third embodiment is the same as the embodiment shown in FIG. 1, and therefore, is not described in detail herein. As the tapered shape is gentle in the third embodiment, growth of the carbon nanotubes 6 at the boundary between the first interlayer insulating film 2 and the second interlayer insulating film 3 is not easily hindered, and the carbon nanotubes 6 can be advantageously grown at a high density.

### Fourth Embodiment

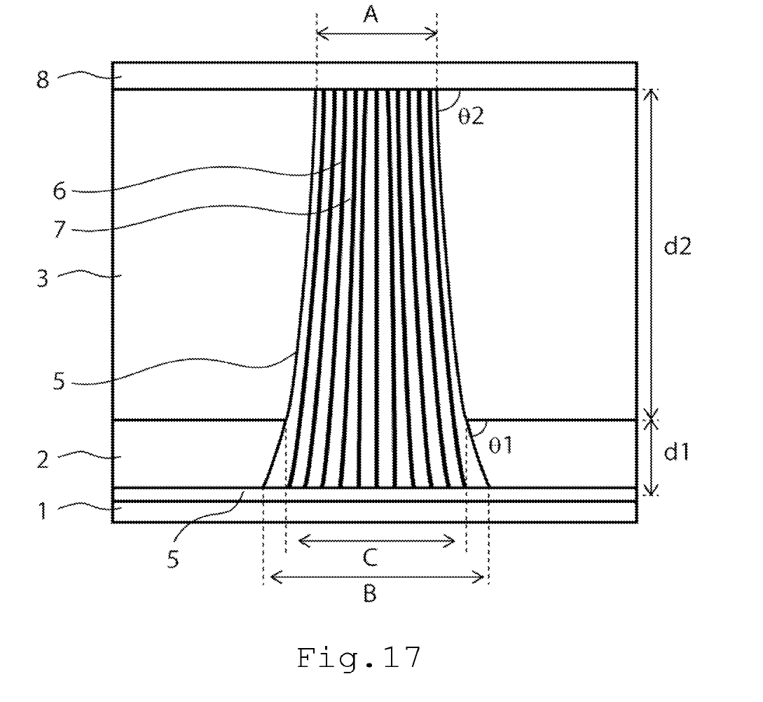

A fourth embodiment is a modification of the embodiment shown in FIG. 9. FIG. 17 is a cross-sectional view of a carbon nanotube interconnect structure of the fourth embodiment. The fourth embodiment differs from the embodiment shown in FIG. 9 in that the angle θ1 is smaller than 90 degrees, and the tapered shape of the sidewall of the contact hole 4 is a curved shape. The curve of the sidewall of the contact hole 4 has an inflection point at the boundary between the first interlayer insulating film 2 and the second interlayer insulating film 3. Except for these aspects, the fourth embodiment is the same as the embodiment shown in FIG. 9, and therefore, is not described in detail herein. Even though the tapered shape of the sidewall of the contact hole 4 is a curved shape, the angles θ1 and θ2 can also be determined from the above equations. As the tapered shape of the fourth embodiment is even gentler than that of the third embodiment, growth of the carbon nanotubes 6 at the boundary between the first interlayer insulating film 2 and the second interlayer insulating film 3 is not easily hindered, and the carbon nanotubes 6 can be advantageously grown at a high density.

### Example 1

Example 1 is an example of a semiconductor device having the carbon nanotube interconnect structure shown in FIG. 1. A Cu metal interconnect having an interconnect width of 300 nm is formed as the first interconnect layer 1 on a substrate. A 50-nm thick SiN film is then formed as the first interlayer insulating film 2 on the first interconnect layer 1 by CVD. A 950-nm thick SiO₂ film is then formed as the second interlayer insulating film 3 on the first interlayer insulating film 2 by CVD. A mask 9 having a circular opening diameter of 100 nm for the contact hole 4 is formed. Dry etching is then performed on the second interlayer insulating film 3 with a CF₄ gas. Dry etching is then performed on the first interlayer insulating film 2 with a CH₂F₂ gas. A 5-nm thick Ni film is then formed as the catalyst metal film 5 in a region including the inside of the contact hole 4 by CVD. After a plasma treatment is performed on the catalyst metal film 5 with a hydrogen gas, a methane gas is supplied to grow the carbon nanotubes 6. A SOD coating liquid is then applied so as to coat the carbon nanotubes 6, and is subjected to a heating treatment at approximately 400° C., to form a SOD film. Polishing is then performed by CMP until the second interlayer insulating film 3 is exposed, and the second interconnect layer 8 having a width of 150 nm is lastly formed so as to be connected to the carbon nanotubes 6. In this manner, the carbon nanotube interconnect structure of Example 1 is obtained. The ratio B/A in the obtained carbon nanotube interconnect structure is 4, and the aspect ratio is 10.

### Example 2

A SiN film is used as the first interlayer insulating film 2, and a SiO₂ film is used as the second interlayer insulating film 3. CF₄ is used as the gas in the dry etching performed on the second interlayer insulating film 3, and CH₂F₂ is used as the gas in the dry etching performed on the first interlayer insulating film 2. Other than that, a carbon nanotube interconnect structure of Example 2 is formed in the same manner as in Example 1. The ratio B/A in the carbon nanotube interconnect structure obtained in Example 2 is 4, and the aspect ratio is 10.

### Example 3

A carbon nanotube interconnect structure of Example 3 is formed in the same manner as in Example 1, except that the opening diameter of the mask 9 is 80 nm, and the interconnect width of the second interconnect layer 8 is 100 nm. The ratio B/A in the carbon nanotube interconnect structure obtained in Example 3 is 5, and the aspect ratio is 12.5.

### Example 4

A carbon nanotube interconnect structure of Example 4 is formed in the same manner as in Example 1, except that the interconnect width of the first interconnect layer 1 is 500 nm, and a 100-nm thick first interlayer insulating film 2 is formed and is then subjected to dry etching. The ratio B/A in the carbon nanotube interconnect structure obtained in Example 4 is 9, and the aspect ratio is 10.5.

### Example 5

A carbon nanotube interconnect structure of Example 5 is formed in the same manner as in Example 1, except that the interconnect width of the first interconnect layer 1 is 200 nm, and a 10-nm thick first interlayer insulating film 2 is formed and is then subjected to dry etching. The ratio B/A in the carbon nanotube interconnect structure obtained in Example 5 is 1.5, and the aspect ratio is 9.6.

### Example 6

A carbon nanotube interconnect structure of Example 6 is formed in the same manner as in Example 1, except that the thickness of the first interlayer insulating film 2 is 100 nm, and the thickness of the second interlayer insulating film 3 is 2900 nm. The ratio B/A in the carbon nanotube interconnect structure obtained in Example 6 is 9, and the aspect ratio is 30.

### Example 7

Example 7 is an example of a semiconductor device having the carbon nanotube interconnect structure shown in FIG. 16. The carbon nanotube interconnect structure of Example 7 is formed in the same manner as in Example 1, except that the etching time for the second interlayer insulating film 3 is longer than that in Example 1. The ratio B/A in the carbon nanotube interconnect structure obtained in Example 7 is 4, and the aspect ratio is 10.

### Example 8

Example 8 is an example of a semiconductor device having the carbon nanotube interconnect structure shown in FIG. 9. A Cu metal interconnect having an interconnect width of 300 nm is formed as the first interconnect layer 1 on a substrate. A 5-nm thick Ni film is deposited as the catalyst metal film 5 on the first interconnect layer 1 by PVD. A 50-nm thick SiN film is then formed as the first interlayer insulating film 2 on the catalyst metal film 5 by CVD. A 950-nm thick SiO₂ film is then formed as the second interlayer insulating film 3 on the first interlayer insulating film 2 by CVD. A mask 9 having a circular opening diameter of 100 nm for the contact hole 4 is formed. Dry etching is then performed on the second interlayer insulating film 3 with a CF₄ gas. Dry etching is then performed on the first interlayer insulating film 2 with a CH₂F₂ gas. After a plasma treatment is performed on the catalyst metal film 5 with a hydrogen gas, a methane gas is supplied to grow the carbon nanotubes 6. A SOD coating liquid is then applied so as to coat the carbon nanotubes 6, and is subjected to a heating treatment at approximately 400° C., to form a SOD film. Polishing is then performed by CMP until the second interlayer insulating film 3 is exposed, and the second interconnect layer 8 having a width of 150 nm is lastly formed so as to be connected to the carbon nanotubes 6. In this manner, the carbon nanotube interconnect structure of Example 8 is obtained. The ratio B/A in the obtained carbon nanotube interconnect structure is 4, and the aspect ratio is 10.

### Example 9

Example 9 is an example of a semiconductor device having the carbon nanotube interconnect structure shown in FIG. 17. The carbon nanotube interconnect structure of Example 9 is formed in the same manner as in Example 8, except that the etching time for the second interlayer insulating film 3 is longer than that in Example 8. The ratio B/A in the carbon nanotube interconnect structure obtained in Example 9 is 4, and the aspect ratio is 10.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A carbon nanotube interconnect structure comprising:
a first interconnect layer;
a first interlayer insulating film on the first interconnect layer;
a second interlayer insulating film on the first interlayer insulating film;
a contact hole penetrating through the first interlayer insulating film and the second interlayer insulating film;
a catalyst metal film on a portion of the first interconnect layer located at a lower end of the contact hole;
a second interconnect layer on the second interlayer insulating film; and
carbon nanotubes on the catalyst metal film located in the contact hole, the carbon nanotubes electrically connecting the first interconnect layer and the second interconnect layer,
wherein
A and B satisfy B/A>1.5, and
L and a satisfy L/a≧2,
where L represents a length of the contact hole,
A represents an opening area at an upper end of the contact hole,
a represents an opening diameter at the upper end of the contact hole, and
B represents an opening area at the lower end of the contact hole.

2. The structure according to claim 1, wherein L and a satisfy L/a≧10.

3. The structure according to claim 1, wherein a density of the carbon nanotubes at the upper end of the contact hole is higher than a density of the carbon nanotubes at the lower end of the contact hole.

4. The structure according to claim 1, wherein d1 and d2 satisfy d1/d2>0.04,
where d1 represents a thickness of the first interlayer insulating film in a penetrating direction of the contact hole, and
d2 represents a thickness of the second interlayer insulating film in the penetrating direction of the contact hole.

5. The structure according to claim 1, wherein A, B, and C satisfy A≦C<B,
where C represents an opening area of the contact hole at an interface between the first interlayer insulating film and the second interlayer insulating film.

6. The structure according to claim 1, wherein θ1 and θ2 satisfy θ2/θ1<2, and θ1≧45°,
where b represents an opening diameter at the lower end of the contact hole,
c represents an opening diameter of the contact hole at an interface between the first interlayer insulating film and the second interlayer insulating film,
cot θ1=(b−c)/2d1, and
cot θ2=(c−a)/2d1.

7. The structure according to claim 1, wherein an insulative or conductive embedded film is provided in a void between the carbon nanotubes.

8. The structure according to claim 1, wherein the opening diameter a is not smaller than 50 nm and not greater than 100 nm.

9. The structure according to claim 1, wherein a density of the carbon nanotubes in a region surrounded by the second interlayer insulating film is 10¹²/cm² or higher.

10. A method of manufacturing a carbon nanotube interconnect structure, comprising:
forming a first interconnect layer;
forming a first interlayer insulating film on the first interconnect layer;
forming a second interlayer insulating film on the first interlayer insulating film;
forming a contact hole penetrating through the first interlayer insulating film and the second interlayer insulating film by performing etching on the first interlayer insulating film and the second interlayer insulating film;
further performing etching on the first interlayer insulating film, to form a larger opening area than an upper end portion of the contact hole;
forming a catalyst metal film in the contact hole;
forming carbon nanotubes on the catalyst metal film;
planarizing the carbon nanotubes; and
forming a second interconnect layer on the planarized carbon nanotubes and the second interlayer insulating film.

11. The method according to claim 10, further comprising performing a treatment to turn the catalyst metal film into nanoparticles, prior to the forming the carbon nanotubes.

12. The method according to claim 10, wherein
the first interlayer insulating film and the second interlayer insulating film have different etching rates from each other, and
an etching gas used in the forming the contact hole differs from an etching gas used in the further performing etching on the first interlayer insulating film.

13. A method of manufacturing a carbon nanotube interconnect structure, comprising:
forming a first interconnect layer;
forming a catalyst metal film on the first interconnect layer;
forming a first interlayer insulating film on the catalyst metal film;
forming a second interlayer insulating film on the first interlayer insulating film;
forming a contact hole penetrating through the first interlayer insulating film and the second interlayer insulating film by performing etching on the first interlayer insulating film and the second interlayer insulating film;
further performing etching on the first interlayer insulating film, to form a larger opening area than an upper end portion of the contact hole;
forming carbon nanotubes on the catalyst metal film;
planarizing the carbon nanotubes; and
forming a second interconnect layer on the planarized carbon nanotubes and the second interlayer insulating film.

14. The method according to claim 13, further comprising
performing a treatment to turn the catalyst metal film into nanoparticles, prior to the forming the carbon nanotubes.

15. The manufacturing method according to claim 13, wherein
the first interlayer insulating film and the second interlayer insulating film have different etching rates from each other, and
an etching gas used in the forming the contact hole differs from an etching gas used in the further performing etching on the first interlayer insulating film.
